(19) United States
(12) Patent Application Publication
(10) Pub. No.: US 2006/0214710 A1
(43) Pub. Date: Sep. 28, 2006

(54) Delay-lock loop and method having high resolution and wide dynamic range

(76) Inventors: Tyler Gomm, Meridian, ID (US); Brandon Roth, Boise, ID (US); Debra Bell, Boise, ID (US)

Correspondence Address: Edward W. Bulchis, Esq.;DORSEY & WHITNEY LLP, Suite 3400, 1420 Fifth Avenue, Seattle, WA, 98101, US

(21) Appl. No.: 11/433,156

(22) Filed: May 11, 2006

Related U.S. Application Data
(63) Continuation of application No. 10/925,711, filed on Aug. 24, 2004.

(51) Int. Cl. H03L 7/06

(52) U.S. Cl. 327/158

(57) ABSTRACT

A delay-lock loop includes a phase detector comparing the phase of a digital input signal to the phase of a feedback signal. The phase detector generates a corresponding control signal that is used to control the delay of a delay line. A multiplexer couples the input signal to the input of the delay line and thereafter couples a signal received from the output of the delay line to the input of the delay line so that the delay line functions as several individual delay lines. At least one digital signal that has propagated through the delay line is used as a feedback signal that is coupled from the output of the delay line to the phase detector by a signal router. The phase of the signal coupled to the phase detector by the router is therefore locked to the phase of the input signal.

### TECHNICAL FIELD

This invention relates to delay-lock loops, and, more particularly, to a delay-lock loop using a delay line that has a high resolution and wide dynamic range, and yet uses relatively little power and requires relatively little circuitry.

### BACKGROUND OF THE INVENTION

It is important to precisely control the timing of digital signals in a wide variety of electronic devices. For example, in memory devices, such as synchronous dynamic random access memory (“SDRAM”) devices, it is desirable to ensure that read data signals are transmitted from the memory devices in synchronism with an external clock signal. Ideally, the start of a data bit should coincide with the rising edge of each clock pulse, or, in the case of double data rate (“DDR”) memory devices, with both the rising and falling edges of each clock pulse. It is also desirable to latch command, address and write data bits in synchronism with the external clock signal using an internal clock signal that is derived from the external clock signal. As the operating speed of memory devices continues to increase, it has become more difficult to provide this synchronism.

One technique for controlling the timing of digital signals, such as the transmission of read data bits and the latching of command, address and write data bits, uses a delay-lock loop. A conventional delay-lock loop 10 is shown in FIG. 1 being used to transmit a read data bit “D” in synchronism with a clock signal “CLK.” The CLK signal is coupled to both a delay line 14 and one input of a phase detector 18. The CLK signal propagates through the delay line 14 to generate an output clock signal CLK_{OUT}, which is applied to the other input of the phase detector 18. The delay of the delay line 14 is controlled by a control signal applied to a control input “C” of the delay line 14. In practice, there is normally some delay between an externally accessible input terminal receiving the CLK signal and the input to the delay line 14. Similarly, there is normally some delay between the output of the delay line 14 and the input to the latch 20 as well as between the output of the latch 20 and the externally accessible data bus terminal 24. A circuit modeling these delays (not shown) is then inserted in the feedback path between the output of the delay line 14 and the input the phase detector 18. However, in the interest brevity and clarity, these delays have been omitted from FIG. 1.

A variety of designs for delay lines have been used. In one delay line design, the CLK signal propagates through a large number of delay elements, such as inverters (not shown), that are coupled in series with each other. The particular delay element to which the CLK signal is applied and/or the CLK_{OUT} signal is taken is adjusted by the control signal to vary the number of delay elements through which the CLK signal propagates.

The phase detector 18 generates an error signal “E” having a magnitude that is proportional to the difference between the phase of the CLK signal and the phase of the CLK_{OUT} signal. The error signal E controls the delay with which the CLK signal is coupled to the delay line 14. Thus, the error signal E controls the phase of the CLK signal relative to the phase of the CLK_{OUT} signal.

In operation, the error signal E adjusts the delay of the delay line 14 to minimize the magnitude of the error signal. If the CLK_{OUT} signal leads the CLK signal, the phase detector 18 generates an error signal E having a polarity that increases the delay of the delay line 14 to reduce the difference between the phase of the CLK_{OUT} signal and the phase of the CLK signal. Conversely, if the CLK_{OUT} signal lags the CLK signal, the phase detector 18 generates an error signal E having a polarity that decreases the delay of the delay line 14 to reduce the difference between the phase of the CLK_{OUT} signal and the phase of the CLK signal. As long as the loop gain of the delay-lock loop 10 is high, the rising and falling edges of the CLK signal will substantially coincide with the rising and falling edges of the CLK_{OUT} signal.

With further reference to FIG. 1, the CLK_{OUT} signal is applied to the clock input of a data latch 20, which receives a read data bit D_{R} at its data input. Read data bits D_{R} are stored in the data latch 20 and coupled to an external data bus terminal 24 responsive to the rising edges (or in the case of a DDR memory device, each rising edge and each falling edge) of the CLK_{OUT} signal. As previously explained, the delay-lock loop 10 synchronizes the CLK_{OUT} signal to the CLK signal. Therefore, the data bit D_{R} will be coupled to the data bus terminal 24 in synchronism with the CLK signal. In the case of command, address and data bits, a data input of a latch (not shown) is coupled to a respective command, address or data bus terminal, and command, address or write data bits are captured by the latches responsive to an internal clock signal. By synchronizing the internal clock signal to the CLK signal, the command, address or write data bits are latched in synchronism with the CLK signal, which is generally coupled to the memory device from the same source as the command, address and write data bits and are thus subject to the same delays.

A delay-lock loop containing several delay lines can also be used to generate multiple phases of a clock signal. As shown in FIG. 2, a delay-lock loop 30 includes the phase detector 18, which again has a first input receiving the CLK signal and a second input receiving the CLK_{OUT} signal from the output of the delay-lock loop 30. The phase detector 18 again produces an error signal E having a magnitude and polarity corresponding to the difference between the phase of the CLK signal and the phase of the CLK_{OUT} signal. The error signal E is coupled to respective control inputs C of four delay lines 32, 34, 36 and 38, each of which include the same number and type of delay elements so that they each produce the same delay. The CLK_{OUT} signal at the output of the last delay-line 38 is locked to the CLK signal, and it thus has a phase of 360° (or 0°) relative to the phase of the CLK signal. As a result, the signal at the output of the delay-line 32 has a phase of 90°, the signal at the output of the delay-line 34 has a phase of 180°, and the signal at the output of the delay-line 36 has a phase of 270°. It will be understood that a greater or lesser number of phases can be generated by using a greater or lesser number of delay lines in a delay-lock loop.

A delay lock loop can also be used to correct the duty cycle of a clock signal using a duty cycle correction circuit, such as a correction circuit 40 shown in FIG. 3. The duty cycle correction circuit 40 receives the four output signals from the delay-lock loop 30 of FIG. 2. The delay-lock loop 30 receives a CLK signal that has a duty cycle other than 50%, e.g., about 63 percent, and it generates from the CLK signal output signals having phases of 0° (or 360°), 90°, 180° and 270° as shown in FIG. 4. The signals having phases of 0° (or 360°), 90°, 180° and 270° also each have a duty cycle of about 63 percent. The 0° signal and the 90° signal are applied to set (“S” ) and reset (“R” ) inputs, respectively, of a set-reset flip-flop 44, which generates a signal “A.” As also shown in FIG. 4, the A signal has a rising edge at 0° relative to the CLK signal and a falling at 90° relative to the CLK signal. Similarly, a second set-reset flip flop 46 receives the 180° and 270° signals at its set (“S” ) and reset (“R” ) terminals, respectively, and it generates a signal “B” at its output that has a rising edge at 180° relative to the CLK signal and a falling at 270° relative to the CLK signal. These two signals A, B are combined by a NOR-gate 48 to provide a signal “C” that has the same frequency as the CLK signal but a duty cycle that has been corrected to 50 percent from the 63 percent duty cycle of the CLK signal. As mentioned above, since the C signal has duty cycle that is 50 percent, its rising and falling edges can be used to couple double data rate data into and out of memory devices. A duty cycle correction circuit can also be implemented by coupling the 0° and 180° signals to set and reset terminals of a flip-flop (not shown).

Although delay-lock loops have been successful in correcting the duty cycle of signals, allowing memory devices to capture and transmit digital signals in synchronism with an external clock signal, and performing other functions, they are not without their limitations and disadvantages. In particular, the resolution and dynamic range of many delay-lock loops are often limited by the resolution and dynamic range of delay lines used in the delay-lock loops. As mentioned above, a common delay line design uses a large number of series-connected delay elements, and the number of delay elements through which an input clock signal is coupled is adjusted to control the delay of the delay line.

Using this delay line design, the maximum delay of the delay line corresponds to the sum of the individual delays of all of the delay elements. While it is easy to make this maximum delay as large as desired by simply increasing the magnitude of the delay provided by each delay element, doing so limits the minimum delay to a relatively large value. Even more significantly, using delay elements having a large delay limits the resolution of the delay line, i.e., the minimum size of the incremental increase or decrease in the delay of the delay line. The resolution of the delay line is therefore limited to the delay produced by each delay element. A delay line having a fine resolution can be produced only by using delay elements having a relatively small delay. As a result of these constraints, a delay line having a high resolution and wide dynamic range requires a very large number of delay elements each having a relatively small delay.

While the use of a large number of delay elements can provide a delay line having a high resolution and a wide dynamic range, doing so results in relatively high cost and power consumption. More specifically, the need to fabricate a large number of delay elements in a memory device increases the expense of such memory devices because of the large amount of surface area of a semiconductor die in which the large number of delay elements are fabricated. Furthermore, as each delay element changes state, it consumes power, and the large number of delay elements needed to provide high resolution and a wide operating range results in a large amount of power being consumed. These disadvantages are even more serious when several delay lines must be used to produce multiple phases of an input clock signal as shown in FIGS. 3 and 4.

There is therefore a need for a delay-lock loop that has a high resolution and a wide dynamic range and yet is relatively inexpensive and consumes relatively little power.

### SUMMARY OF THE INVENTION

A delay-lock loop and method uses a delay line to which a digital input signal is initially applied. The input signal propagates through the delay line and is then coupled back to the input of the delay line one or more times. One of the signals that is coupled through the delay line is coupled to a phase detector that also receives the digital input signal. The phase detector generates a control signal that is used to control the delay of the delay line. As a result, the phase of the signal coupled from the output of the delay line is locked to the phase of the input signal, and each digital signal that previously propagated through the delay line has a predetermined phase relative to the phase of the input signal. Multiple phases of the input signal can be coupled to a duty cycle correction circuit or to clock inputs of latches that latch signals into or out of an electronic device.

### BRIEF DESCRIPTION OF THE DRAWINGS

FIG. 1 is a block diagram of a conventional delay-lock loop.

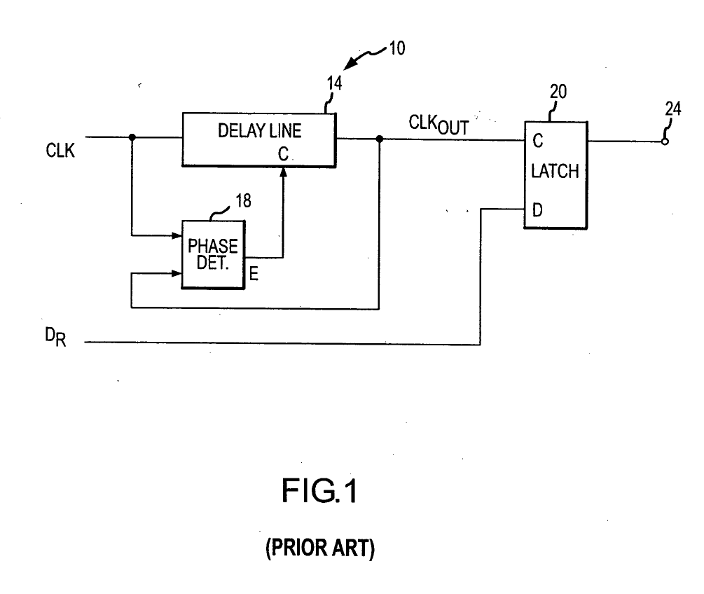

FIG. 2 is a block diagram of a conventional delay-lock loop using several delay lines to produce multiple phases of a clock signal.

FIG. 3 is a block diagram of a conventional duty cycle correction circuit that can be used with the delay-lock loop of FIG. 2.

FIG. 4 is a timing diagram showing waveforms present in the duty cycle correction circuit of FIG. 3.

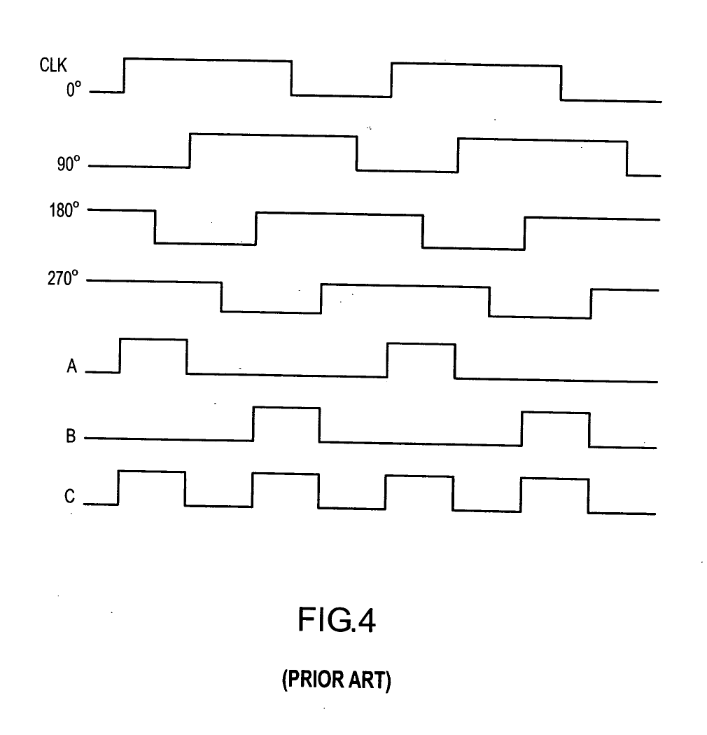

FIG. 5 is a block diagram of a delay-lock loop according to one embodiment of the invention.

FIGS. 6A-6B are block diagrams of the delay-lock loop of FIG. 5 shown in various states of operation.

FIG. 7 is a timing diagram showing waveforms present in the delay-lock loop of FIG. 5.

FIG. 8 is a logic diagram showing an embodiment of a multiplex controller that is used in the delay-lock loop of FIG. 5.

FIG. 9 is a logic diagram showing an embodiment of a multiplexer that is used in the delay-lock loop of FIG. 5.

FIG. 10 is a logic diagram showing an embodiment of a multiplex controller that is used in the delay-lock loop of FIG. 5 to control the operation of the multiplexer of FIG. 9.

FIG. 11 is a block diagram of a delay-lock loop according to another embodiment of the invention.

FIG. 12 is a timing diagram showing waveforms present in the delay-lock loop of FIG. 11.

FIG. 13 is a block diagram of a frequency doubler circuit using the multi-phase clock signals generated by the delay-lock loop of FIG. 11.

FIGS. 14A-G are timing diagrams showing the operation of the frequency doubler circuit of FIG. 13.

FIG. 15 is a block diagram of a memory device using at least one delay-lock loop according to various embodiments of the invention.

FIG. 16 is a block diagram of a computer system using the memory device of FIG. 15.

### DETAILED DESCRIPTION

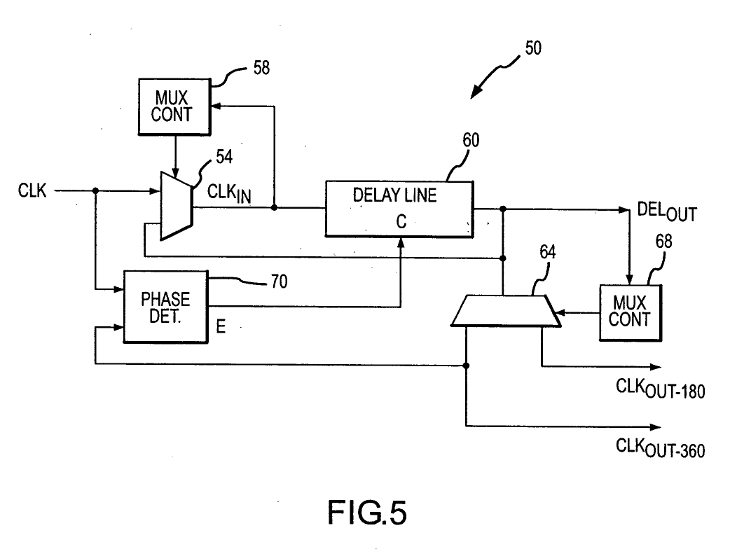

A delay-lock loop 50 according to one embodiment of the invention is shown in FIG. 5. The delay-lock loop 50 receives a clock signal CLK, which is coupled to one input of a multiplexer 54. A second input of the multiplexer 54 receives a signal, the nature of which will be described in greater detailed below. The multiplexer 54 selects one of these two signals for use as a CLK_{IN} signal that is coupled to the output of the multiplexer 54. The operation of the multiplexer 54 is controlled by a multiplex controller 58 that receives the CLK_{IN} signal.

The CLK_{IN} signal at the output of the multiplexer 54 is coupled to a delay line 60, which generates a delay output signal DEL_{OUT} that is delayed in time relative to the signal applied to the CLK_{IN}signal. The magnitude of the delay is determined by a control signal applied to a control input “C” of the delay line 60. The delay line 60 may be a conventional delay line composed of a plurality of series-connected delay elements or some other type of presently known or future developed delay line.

The DEL_{OUT} signal at the output of the delay line 60 is coupled to the input of the multiplexer 54. Thus, when the multiplexer 54 applies the DEL_{OUT} signal to the input of the delay line 60, the CLK_{IN} signal, in effect, propagates through the delay line 60 a second time. The DEL_{OUT} signal is also applied to the input of a multiplexer 64 that either coupled the DEL_{OUT} signal to a CLK_{OUT-180} terminal, or feeds the DEL_{OUT} signal back to an input of a phase detector 70 and couples it to a CLK_{OUT-360} terminal. Another input of the phase detector 70 receives the CLK signal that is applied to the multiplexer 54. As before, the phase detector 70 generates an error signal “E” that controls the delay of the delay line 60. The operation of the multiplexer 64 is controlled by a multiplex controller 68, which also receives the DEL_{OUT} signal from the delay line 60.

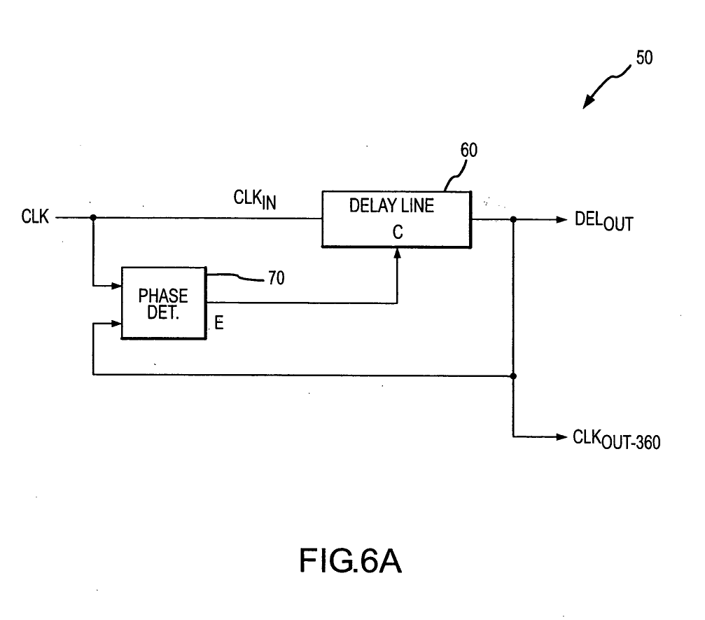

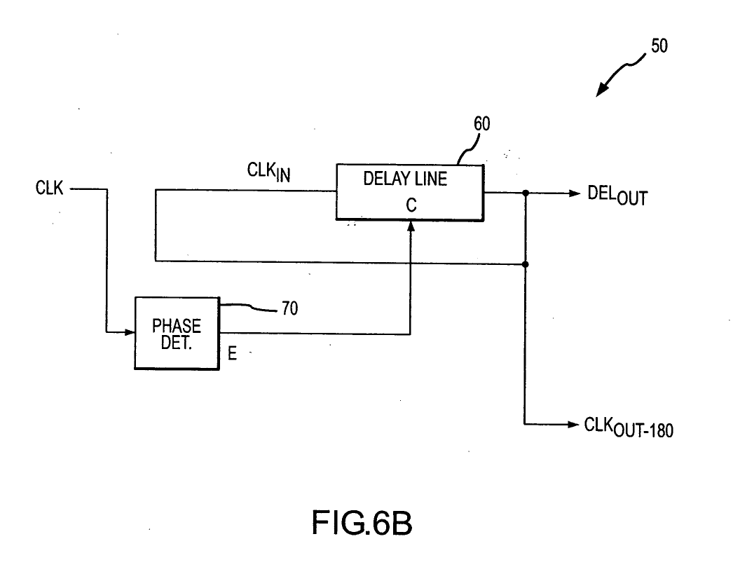

The operation of the delay-lock loop 60 will be explained with reference to FIGS. 6A-6B which show the topography of the delay-lock loop 50 in different states as determined by the multiplexers 54, 64. The delay-lock loop 60 initially has the topography shown in FIG. 6A so that the multiplexer 54 couples the CLK signal to the delay line 60. However, the rising edge of the CLK signal causes the multiplex controller 58 to switch the multiplexer 54 to the topography shown in FIG. 6B. When the multiplexer 54 switches responsive to the rising edge of the CLK signal, it truncates the CLK signal to the CLK_{IN} signal shown in FIG. 7, which is applied to the input of the delay line 60. Also, the rising edge of the DEL_{OUT} signal, which occurs at the same time as the rising edge of the CLK signal if the delay-lock loop 50 is locked, causes the multiplex controller 68 to switch the multiplexer 64 to the topography shown in FIG. 6B so that the output of the multiplexer 64 to the CLK_{OUT-180} terminal.

With further reference to FIG. 6B, the CLK_{IN} signal propagates through the delay line 60 to produce the DEL_{OUT} signal, which is also shown in FIG. 7. In the embodiment shown in FIG. 5, the delay line 60 delays the CLK_{IN} signal by one-half the period of the CLK signal, i.e., 180 degrees, for reasons that will become apparent. The multiplexer 64 then couples this DEL_{OUT} signal back to the input of the delay line 60 and to the CLK_{OUT-180} terminal through the multiplexer 54. The delay line 60 is thus “re-used” to generate another DEL_{OUT} signal, as also shown in FIG. 7.

The DEL_{OUT} signal resulting from the CLK signal being coupled through the delay line 60 causes the multiplex controllers 58, 68 to switch the multiplexers 54, 64, respectively, so that the delay-lock loop 50 has the topography shown in FIG. 6A. In this topography, the DEL_{OUT} signal is coupled to both the CLK_{OUT-360} terminal of the delay-lock loop and to an input of the phase detector 70. The error signal E generated by the phase detector 70 controls the delay of the delay-lock loop 60 so that the phase of the second DEL_{OUT} signal is substantially equal to the phase of the CLK signal. The second DEL_{OUT} signal coupled to the CLK_{OUT-360} terminal thus has the same phase as the CLK signal, and the first DEL_{OUT} signal coupled to the CLK_{OUT-180} terminal has a phase of 180 degrees relative to the phase of the CLK signal. The delay-lock loop 50 thus performs substantially the same function as a delay-lock loop using two delay lines coupled in series with each other. However, it does so using half the number of delay elements that would otherwise be required since the delay line 50 is re-used, as explained above. As a result, the delay line 50 may consume less power and would occupy less space on a semiconductor die than a delay-lock loop using two separate delay lines coupled in series with each other. Furthermore, by generating these multiply phased signals without using separate delay lines, there is no need to ensure perfect matching of multiple delay lines.

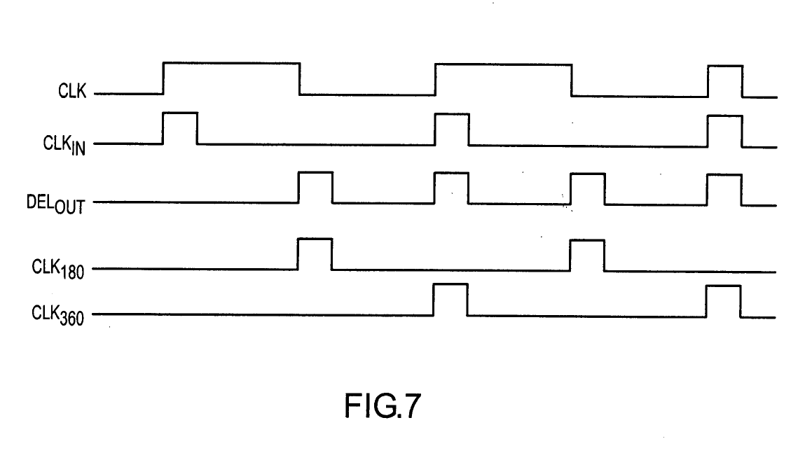

One embodiment of the multiplexer controller 58 is shown in FIG. 8. The multiplex controller 58 includes a D flip-flop 80 having a clock “C” input to which the CLK_{IN} signal at the output of the multiplexer 54 is coupled and a clock compliment C* input to which the CLK_{IN} signal is coupled through an inverter 84. The flip flop 80 also has a reset “R” input to which a reset “RST” signal is applied to reset the flip flop 80. A “Q” output of the flip-flop 80 is coupled to the input of an inverter 86, and the output of the inverter 86 is coupled to a data “D” input of the flip-flop 80. The Q output of the flip-flop 80 is also applied to an input of a delay circuit 88 that delays the switching of the multiplexer 54 for a short time after a signal at the Q output of the flip-flop 80 transitions from one state to another. The delay circuit 88 controls the truncation of the CLK signal and each DEL_{OUT} signal coupled through the multiplexer 54 after the rising edge of each signal has been coupled through the multiplexer 54.

In operation, the flip-flop 80 is reset by the “RST” signal to cause the flip-flop 80 to output a low signal at its Q output. The low Q output signal causes the multiplexer 54 to couple the CLK signal to the output of the multiplexer 54. As a result, the CLK signal is coupled to the input of the delay line 60, as previously explained. When the rising edge of the CLK signal is coupled through the multiplexer 54, the resulting rising edge of the CLK_{IN} signal causes the flip-flop 80 to toggle so that it generates a high output signal. The high output signal at the output of the flip-flop 80 switches the multiplexer 54 so that it now couples the output of the DEL_{OUT} signal at the output of the multiplexer 64 to the output of the multiplexer 54. However, the rising edge of the DEL_{OUT} signal causes the flip-flop 80 to toggle so it generates a low output that causes the multiplexer 54 to again couple the CLK signal to its output. In summary, the multiplex controller 58 controls the operation of the multiplexer 54 so that the CLK signal is initially applied to the delay line 60. The multiplex controller 58 then causes the DEL_{OUT} signal resulting from coupling the CLK signal through the delay line 60 to be coupled to the input of the delay line 60, thereby re-using the delay line 60 to generate a second DEL_{OUT} signal.

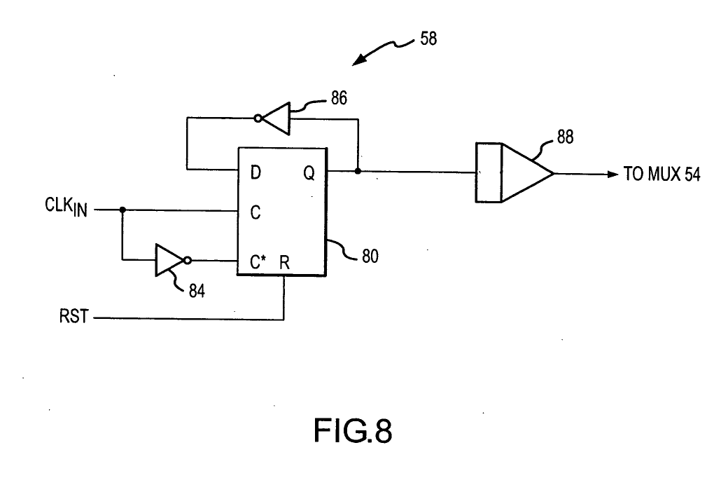

One embodiment of the multiplexer 64 is shown in FIG. 9. The multiplexer 64 includes a NOR gate 90 having an input to which the output of the delay line 60 is coupled through an inverter 92. The other input of the NOR gate 90 receives the control signal from the multiplex controller 68. When the control signal is low, the NOR gate 90 is enabled to pass the DEL_{OUT} signal at the output of the delay line 60 to the output of the NOR gate 90. The output of the NOR gate 90 is coupled to the input of the phase detector 70 and to the CLK_{OUT-360} terminal.

The multiplexer 64 also includes a NAND gate 94 having an input to which the output of the delay line 60 is coupled. The other input of the NAND gate 94 receives the control signal. When the control signal is high, the NAND gate 94 is enabled to pass the DEL_{OUT} signal at the output of the delay line 60 to the output of the NAND gate 94. This output is further inverted by an inverter 96 so that, when the NAND gate 94 is enabled, the signal at the output of the NAND gate 94 has the same logic level as the DEL_{OUT} signal at the output of the delay line 60. The output of the NAND gate 94 is coupled to the CLK_{OUT-180} terminal. The multiplexer 64 therefore couples the DEL_{OUT} signal to the CLK_{OUT-180} terminal when the control signal is low, and it couples the DEL_{OUT} signal to the input of the phase detector 70 when and to the CLK_{OUT-360} when the control signal is high.

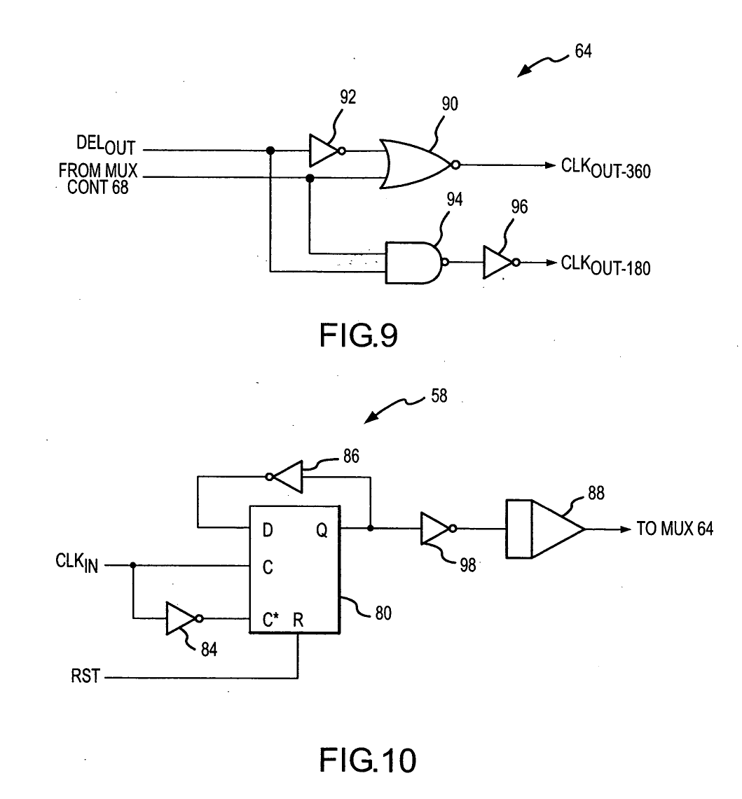

One embodiment of the multiplexer controller 68 for controlling the operation of the multiplexer 64 is shown in FIG. 10. The multiplex controller 68 is substantially the same as the multiplex controller 58 shown in FIG. 8. Therefore, in the interest of brevity, identical components in both multiplex controllers 58, 68 have been provided with the same reference numerals, and an explanation of their function and operation will not be repeated. The multiplex controller 68 differs from the multiplex controller 58 of FIG. 8 in the use of an inverter 98 between the Q output of the flip-flop 80 and the input of the delay circuit 88.

In operation, the flip-flop 80 is again reset by the “RST” signal to cause the flip-flop 80 to output a low signal at its Q output. The low Q output signal causes the inverter 98 to output a high signal that, after being coupled through the delay circuit 88, causes the multiplexer 64 to couple the output of the delay line 60 to the CLK_{OUT180} terminal, as explained above with reference to FIG. 9. When the CLK signal has been coupled through the delay line 60 to generate a first DEL_{OUT} signal, the rising edge of the DEL_{OUT} signal toggles the flip-flop 80 so that the inverter 98 now outputs a low control signal. The low control signal causes the multiplexer 64 to couple the output of the DEL_{OUT} signal at the output of the delay line 60 to the phase detector 70 and to the CLK_{OUT-360} terminal.

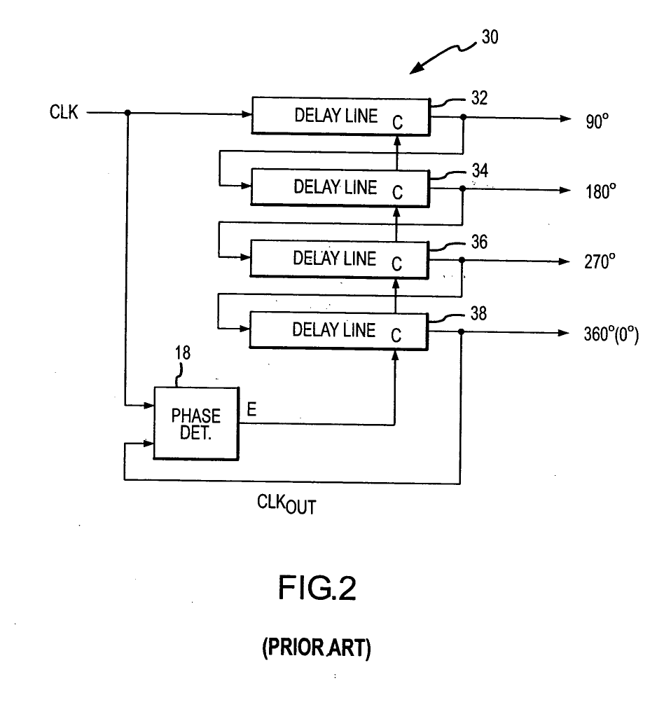

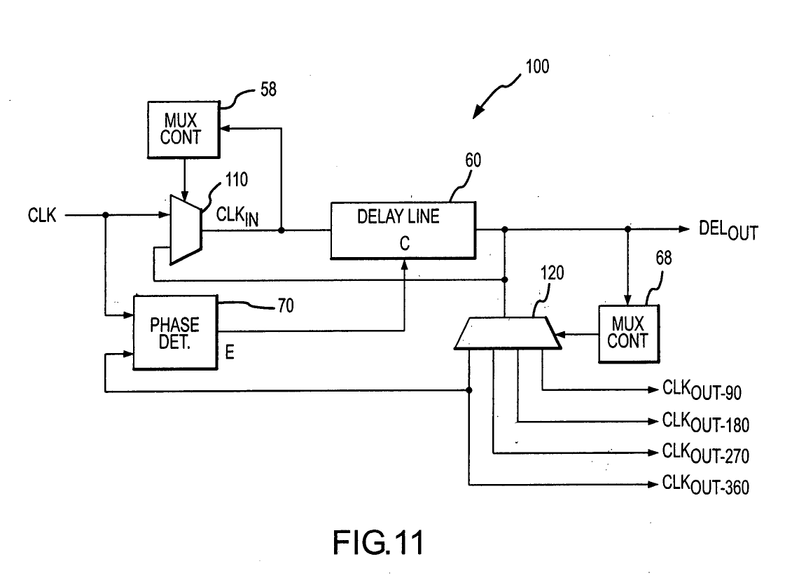

The delay line 60 in the delay-lock loop 50 is “re-used” only once by coupling the DEL_{OUT} signal at the output of the delay line 60 to its input only once as in the delay-lock loop 50 of FIG. 5. However, the delay line 60 can be “re-used” multiple times by repeatedly coupling the DEL_{OUT} signal at the output of the delay line 60 to its input. For example, the delay-lock loop 30 shown in FIG. 2 can be implemented using the delay-lock loop 100 shown in FIG. 11. The delay lock loop 100 is similar to the delay-lock loop 50 of FIG. 5. In the interest of brevity, components in both delay-lock loops 50, 100 that are identical to each other have been provided with the same reference numerals, and an explanation of their function and operation will not be repeated. The delay-lock loop 100 differs from the delay-lock loop 50 of FIG. 5 by substituting a multiplexer 110 in place of the multiplexer 54 that passes multiple DEL_{OUT} signals to the input of the delay line 60 before again coupling the CLK signal to the input of the delay line 60. The delay-lock loop 100 also differs from the delay-lock loop 50 by using a multiplexer 120 having additional outputs in place of the multiplexer 64 used in the delay-lock loop 50. The multiplexer 110 includes suitable circuitry, such as a counter (not shown), to maintain the output of the delay line 60 coupled to the input of the delay line 60 until a predetermined number of DEL_{OUT} signals have been coupled to the input of the delay line 60. Similarly, the multiplexer 120 includes suitable circuitry, such as a counter and multiplexer (not shown), to couple each DEL_{OUT} signal to a respective output terminal, i.e., a CLK_{OUT-90} terminal, a CLK_{OUT-180}, a CLK_{OUT-270}, and CLK_{OUT-360} terminal. If a counter is used, the counter may reside in a component other than the multiplexer 120, such as in the multiplex controller 68.

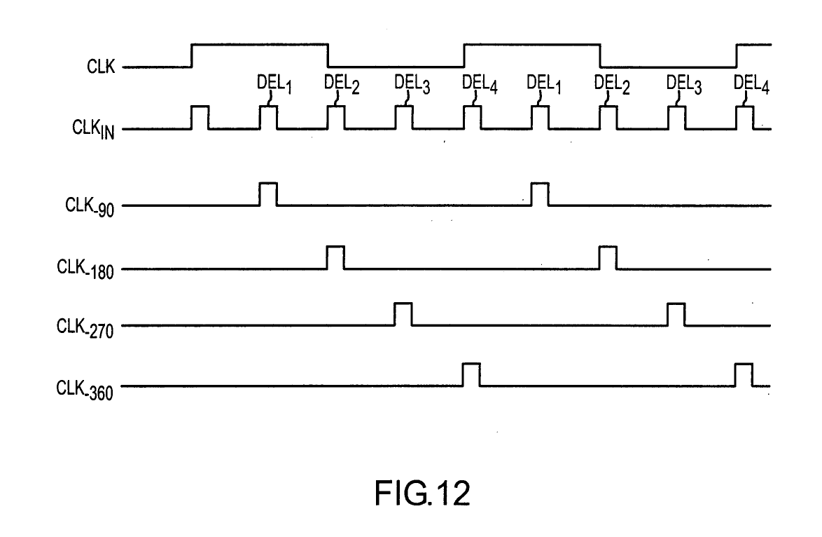

The operation of the delay-lock loop 100 of FIG. 11 will now be explained with reference to the timing diagram shown in FIG. 12. The multiplexer 110 initially couples the CLK signal to its output to generate the CLK_{IN} signal. The CLK_{IN} signal propagates through the delay line 60 to produce a first DEL_{OUT} signal, which is also shown in FIG. 7 and labeled “DEL₁.” In the embodiment shown in FIG. 11, the delay line 60 delays the CLK_{IN} signal by one-quarter of the period of the CLK signal, i.e., 90 degrees, for reasons that will become apparent. The multiplexer 120 couples the first DEL_{OUT} signal, i.e., the DEL₁ signal, to the CLK_{OUT-90} terminal.

As soon as the CLK signal was coupled through the multiplexer 110 to generate the CLK_{IN} signal, the CLK_{IN} signal causes the multiplex controller 58 to switch the multiplexer 110. Thereafter, a counter or other circuitry in the multiplexer controller 68 or other component causes the multiplexer 120 to couple the input of the multiplexer 120 to each output in sequence responsive to each DEL_{OUT} signal from the delay line 60. As a result, the multiplexer 110 couples the first DEL_{OUT} signal to the input of the delay line 60. The first DEL_{OUT} signal propagates through the delay line 60 to produce a second DEL_{OUT} signal, which is also shown in FIG. 12 and labeled “CLK_{OUT-180}.38 The multiplexer 120 then couples the CLK_{OUT-180} signal to the CLK_{OUT-180} terminal. In like manner, the multiplexer 110 couples the second DEL_{OUT} signal to the delay line 60 so that it propagates through the delay line 60 to produce a third DEL_{OUT} signal, which is labeled “CLK_{OUT-270}.” The multiplexer 120 couples the third DEL_{OUT} signal to the CLK_{OUT-270} terminal. Finally, the multiplexer 110 couples the CLK_{OUT-270} signal to the delay line 60 so that it propagates through the delay line 60 to produce a fourth DEL_{OUT} signal.” The multiplexer 120 couples the fourth DEL_{OUT} signal to the CLK_{OUT-360} terminal and to the input of the phase detector 70. The CLK_{OUT-360} signal thus has the same phase as the CLK signal, and the CLK_{OUT-90}, CLK_{OUT-180} and CLK_{OUT-270} signals have phases of 90, 180 and 270 degrees, respectively, relative to the phase of the CLK signal.

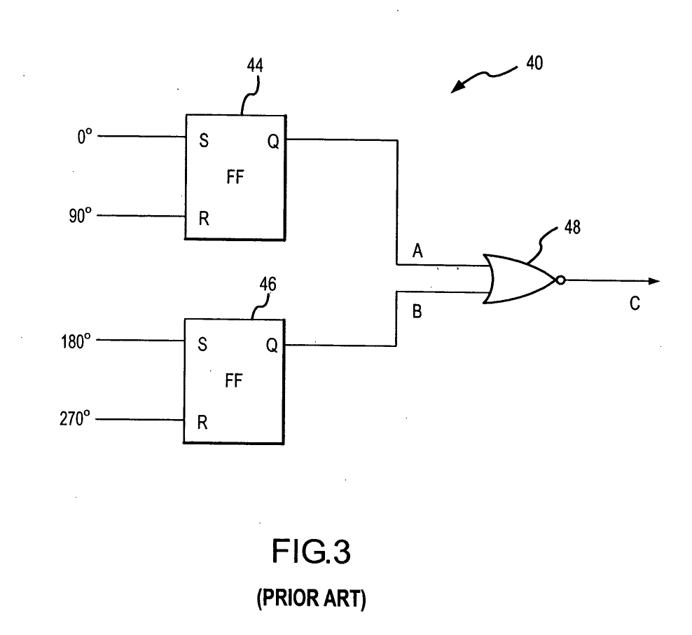

By “re-using” the delay line 60 four times, the delay-lock loop 100 may use substantially less power and consumes substantially less surface on a semiconductor die compared to the delay-lock loop 30 shown in FIG. 3 because the delay-lock loop 100 has only one-quarter of the delay elements used in the delay-lock loop 30. The delay line 60 may be used any number of times by passing a corresponding number of DEL_{OUT} signals back to the input of the delay line 60. Again, by generating these signals having multiple phases without using separate delay lines, there is no need to ensure perfect matching of multiple delay lines.

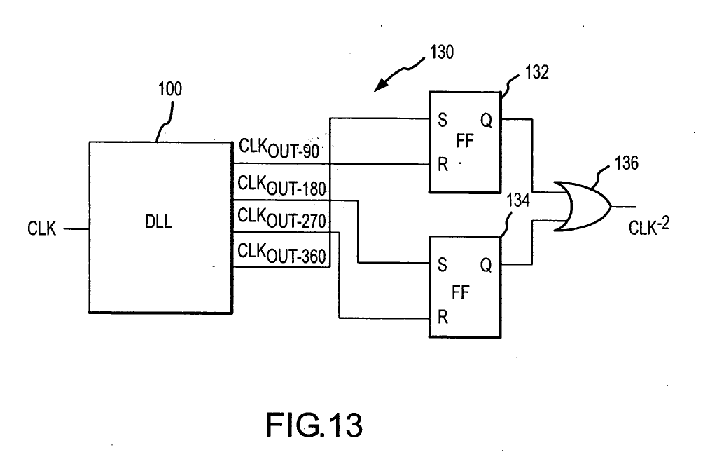

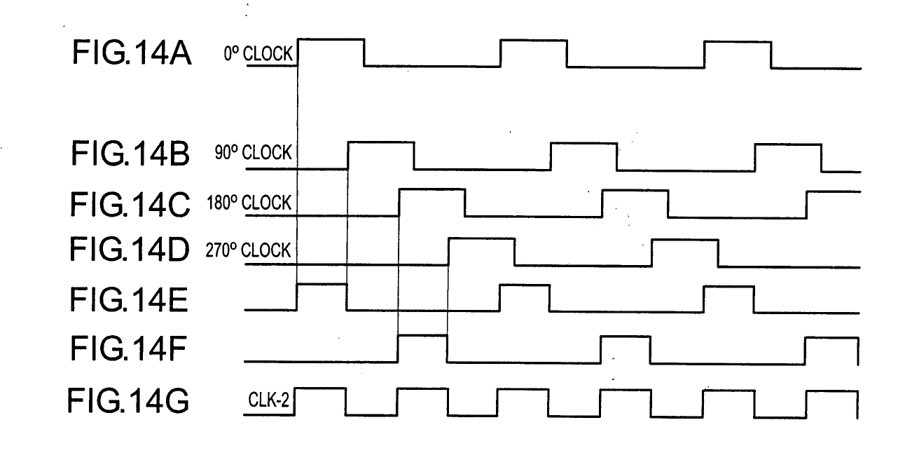

Various embodiments of the invention can be used to generate clock signals having frequencies that are a multiple of the frequency of the frequency of the CLK signal. With reference to FIG. 13, a frequency doubler circuit 130 uses the delay-lock loop 100 shown in FIG. 11 to generate the four output signals CLK_{OUT-90}, CLK_{OUT-180}, CLK_{OUT-270} and CLK_{OUT-360}, which are phased 90 degrees from each other. The CLK signal is shown in FIG. 14A, and the CLK_{OUT-90}, CLK_{OUT-18O}, and CLK_{OUT-270} signals are shown in FIGS. 14B-14D, respectively. The CLK_{OUT-360} signal is assumed to be identical to the CLK signal shown in FIG. 14A. The frequency doubler circuit 130 further includes a pair of set/reset flip-flops 132, 134 that are coupled to receive the output signals from the delay-lock loop 100. The first flip-flop 132 is set by the CLK_{OUT-360} output signal and reset by the CLK_{OUT-90} signal. The output of the flip-flop 132 is therefore a signal that transitions high at (or 0) degrees and transitions low at 90 degrees, as shown in FIG. 14E. Similarly, the second flip-flop 134 is set by the CLK_{OUT-180} output signal and reset by the CLK_{OUT-270} signal. The output of the flip-flop 134 is therefore a signal that transitions high at 180 degrees and transitions low at 270 degrees, as shown in FIG. 14F. The outputs of the flip-flops 132, 134 are combined by a NOR gate 136 to generate the CLK-2 signal shown in FIG. 14G, which has twice the frequency of the CLK signal.

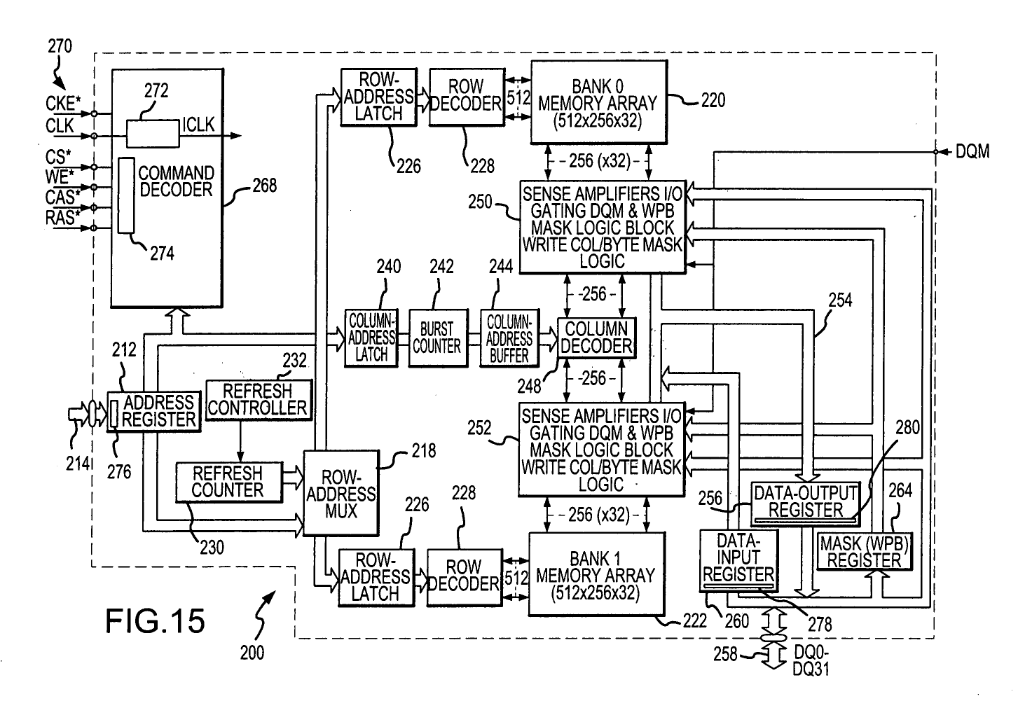

A memory device using one or more delay-lock loops according to an embodiment of the invention is shown in FIG. 15. The memory device is a synchronous dynamic random access memory (“SDRAM”) device 200, although the delay-lock loop according to various embodiments of the invention may also be used in other types of memory devices and in electronic circuits other than memory devices as well as in different types of SDRAM devices, such as double data rate (“DDR”) SDRAM devices. The SDRAM 200 includes an address register 212 that receives either a row address or a column address on an address bus 214. The address bus 214 is generally coupled to a memory controller (not shown). Typically, a row address is initially received by the address register 212 and applied to a row address multiplexer 218. The row address multiplexer 218 couples the row address to a number of components associated with either of two memory banks 220, 222 depending upon the state of a bank address bit forming part of the row address. Associated with each of the memory banks 220, 222 is a respective row address latch 226, which stores the row address, and a row decoder 228, which applies various signals to its respective array 220 or 222 as a function of the stored row address. The row address multiplexer 218 also couples row addresses to the row address latches 226 for the purpose of refreshing the memory cells in the arrays 220, 222. The row addresses are generated for refresh purposes by a refresh counter 230, which is controlled by a refresh controller 232.

After the row address has been applied to the address register 212 and stored in one of the row address latches 226, a column address is applied to the address register 212. The address register 212 couples the column address to a column address latch 240. Depending on the operating mode of the SDRAM 200, the column address is either coupled through a burst counter 242 to a column address buffer 244, or to the burst counter 242 which applies a sequence of column addresses to the column address buffer 244 starting at the column address output by the address register 212. In either case, the column address buffer 244 applies a column address to a column decoder 248 which applies various signals to respective sense amplifiers and associated column circuitry 250, 252 for the respective arrays 220, 222.

Data to be read from one of the arrays 220, 222 is coupled to the column circuitry 250, 252 for one of the arrays 220, 222, respectively. The data is then coupled through a read data path 254 to a data output register 256, which applies the data to a data bus 258. Data to be written to one of the arrays 220, 222 is coupled from the data bus 258, a data input register 260 and a write data path 262 to the column circuitry 250, 252 where it is transferred to one of the arrays 220, 222, respectively. A mask register 264 may be used to selectively alter the flow of data into and out of the column circuitry 250, 252, such as by selectively masking data to be read from the arrays 220, 222.

The above-described operation of the SDRAM 200 is controlled by a command decoder 268 responsive to command signals received on a command bus 270. These high level command signals, which are typically generated by a memory controller (not shown), are a clock enable signal CKE*, a clock signal CLK, a chip select signal CS*, a write enable signal WE*, a row address strobe signal RAS*, and a column address strobe signal CAS*, which the “*” designating the signal as active low. Various combinations of these signals are registered as respective commands, such as a read command or a write command. The command decoder 268 generates a sequence of control signals responsive to the command signals to carry out the function (e.g., a read or a write) designated by each of the command signals. These command signals, and the manner in which they accomplish their respective functions, are conventional. Therefore, in the interest of brevity, a further explanation of these control signals will be omitted.

The CLK signal may be used to generate an internal clock signals by coupling the CLK signal to a clock generator circuit 272 that uses one of the delay lines 50 (FIG. 5), 100 (FIG. 11) or some other embodiment of the invention. The internal clock signals generated by the clock generator circuit 272 are coupled to command latches, generally indicated as 274, that latch command signals into the command decoder 268 from the command bus 270. Similarly, internal clock signals generated by the clock generator circuit 272 latch address signals from the address bus 214 into address latches 276 in the address register 212. The internal clock signals from the clock generator circuit 272 also latch write data signals from the data bus 258 into data input latches 278 in the data input register 260. Finally, the internal clock signals generated by the clock generator circuit 272 are coupled to data output latches 280 in the data output register 256 to couple read data signals to the data bus 258.

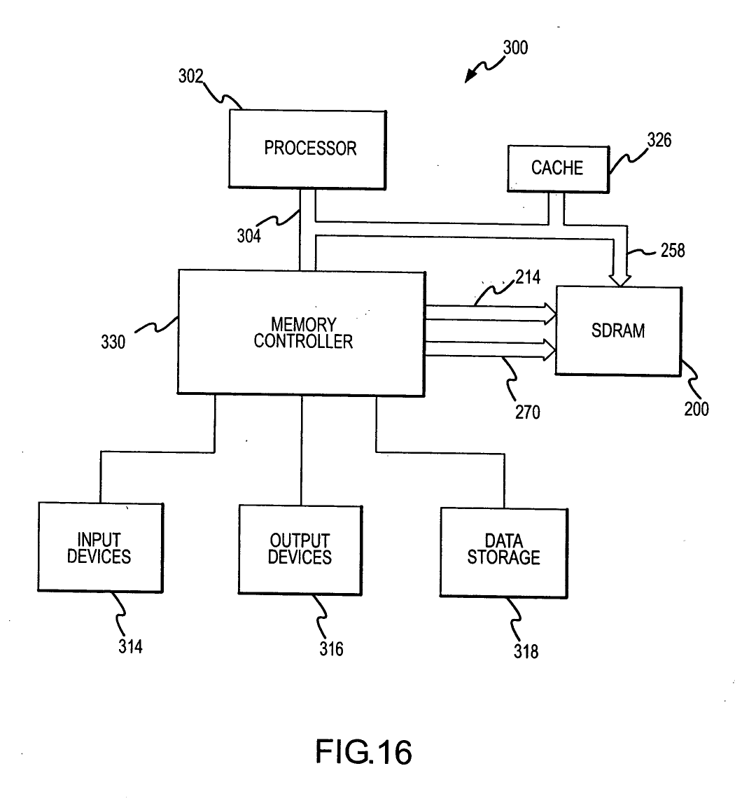

FIG. 16 shows a computer system 300 containing the SDRAM 200 of FIG. 15. The computer system 300 includes a processor 302 for performing various computing functions, such as executing specific software to perform specific calculations or tasks. The processor 302 includes a processor bus 304 that normally includes an address bus, a control bus, and a data bus. In addition, the computer system 300 includes one or more input devices 314, such as a keyboard or a mouse, coupled to the processor 302 to allow an operator to interface with the computer system 300. Typically, the computer system 300 also includes one or more output devices 316 coupled to the processor 302, such output devices typically being a printer or a video terminal. One or more data storage devices 318 are also typically coupled to the processor 302 to allow the processor 302 to store data in or retrieve data from internal or external storage media (not shown). Examples of typical storage devices 318 include hard and floppy disks, tape cassettes, and compact disk read-only memories (CD-ROMs). The processor 302 is also typically coupled to cache memory 326, which is usually static random access memory (“SRAM” ), and to the SDRAM 200 through a memory controller 330. The memory controller 330 normally includes the control bus 270 and the address bus 214 that are coupled to the SDRAM 200. The data bus 258 is coupled from the SDRAM 200 to the processor bus 304 either directly (as shown), through the memory controller 330, or by some other means.

Although the present invention has been described with reference to the disclosed embodiments, persons skilled in the art will recognize that changes may be made in form and detail without departing from the spirit and scope of the invention. Such modifications are well within the skill of those ordinarily skilled in the art. Accordingly, the invention is not limited except as by the appended claims.

1. A method of delaying a digital signal, comprising:
applying the digital signal to an input terminal of a delay line;
allowing each signal coupled to the input terminal of the delay line to propagate to an output terminal of the delay line; and
routing at least one signal that is present at the output terminal of the delay line to the input terminal of the delay line.

2-49. (canceled)
